(19) United States
(12) Patent Application Publication
(10) Pub. No.: US 2026/0145165 A1
(43) Pub. Date: May 28, 2026

(54) BACKSIDE POLISHING ADDITIVE FOR REDUCING ALKALI CONSUMPTION AND PREPARATION METHOD AND USE THEREOF

(71) Applicants: Gengxin HAN, Friescovita, TX (US); Bing Han, Friescovita, TX (US)

(72) Inventors: Gengxin HAN, Friescovita, TX (US); Bing Han, Friescovita, TX (US)

(21) Appl. No.: 19/271,915

(22) Filed: Jul. 17, 2025

(30) Foreign Application Priority Data
Nov. 22, 2024 (CN) 202411682904.7

(51) Int. Cl. B01J 31/02; B01J 31/04; B01J 31/06; B01J 35/27; B01J 37/04; C09K 13/02; H01L 21/306; H10F 77/70

(52) U.S. Cl. CPC B01J 31/0235; B01J 31/04; B01J 31/061; B01J 35/27; B01J 37/04; C09K 13/02; H10P 50/642; H10F 77/707

(57) ABSTRACT

The present disclosure discloses a backside polishing additive for reducing alkali consumption, and a preparation method and a use thereof. The backside polishing additive includes components in percentages by mass as follows: 0.01% to 0.5% of a catalyst containing a nitrobenzene structure, 0.1% to 1% of a defoaming agent, 0.5% to 1.5% of a preservative, and the balance of water. The additive of the present disclosure enables a polishing reaction at a required alkali concentration or consumption lower than the conventional additive. Therefore, the present additive has more significant alkali-reducing capability than the conventional additive. Additionally, the silicon wafer obtained through the use of the additive of the present disclosure to conduct the alkali polishing reaction has a surface with a good flatness of the tower base and a high reflectivity, indicating a superior polishing effect, and resulting in a significant enhancement of the cell efficiency.

### CROSS REFERENCE TO THE RELATED APPLICATIONS

This application is based upon and claims priority to Chinese Patent Application No. 202411682904.7, filed on Nov. 22, 2024, the entire contents of which are incorporated herein by reference.

### TECHNICAL FIELD

The present disclosure belongs to the technical field of backside polishing of silicon wafers, and specifically relates to a backside polishing additive for reducing alkali consumption, and a preparation method and a use thereof.

### BACKGROUND

The backside polishing process is an important part in the production of photovoltaic cells. The main objective of this process is to polish a velvet surface on a backside of a silicon wafer to change a pyramid structure into a tower base structure. The flat tower base structure can increase the internal reflection of transmitted light on the backside of the silicon wafer, to allow the light to return to the inside of the silicon wafer again, thereby increasing utilization of the light and improving the photovoltaic conversion efficiency. In addition, improving the flatness of the backside of the silicon wafer is also beneficial to the increase of denseness and uniformity of a backside passivation film, thereby enhancing the passivation effect.

The silicon wafer backside polishing processes mainly include acid polishing and alkali polishing. In the acid polishing, nitric acid and hydrofluoric acid are used to etch the backside of the silicon wafer, while in the alkali polishing, alkali is used for etching. At present, mainstream processes all adopt alkali polishing for backside polishing of silicon wafers. An alkaline solution containing sodium hydroxide (NaOH) or potassium hydroxide (KOH) is often used in a large amount in the alkali polishing production process. However, the use of these chemicals generates emissions and causes environmental pollution, and also has a significant negative impact on production costs. In response to these problems, the industry has currently adopted an alkali polishing additive to optimize the alkali polishing production process. The alkali polishing additive mainly serves to improve the surface flatness of the silicon wafer, reduce defects of the surface, and meanwhile reduce alkali consumption in the alkali polishing process. Although the use of a conventional alkali polishing additive can reduce the alkali consumption to some extent, its ability to reduce the alkali consumption is moderate. Currently, there has been no alkali polishing additive with significant alkali-reducing capability available on the market. Therefore, considering the competition in the industry as well as the urgent demand for cost decrease and benefit increase and reduction of environmental pollution, there is an urgent need in the market for an alkali polishing additive that can significantly reduce the alkali consumption and improve the cell efficiency.

### SUMMARY

Objective of the present disclosure: Regarding the above technical problems, an objective of the present disclosure is to provide a backside polishing addictive for significantly reducing alkali consumption in an alkali polishing production process, and enhancing the conversion efficiency, and a preparation method and a use thereof. The present additive allows sufficient etching of a backside of a silicon wafer with NaOH or KOH at a low concentration, thereby improving the polishing effect on a surface of the silicon wafer. Therefore, compared with the conventional alkali polishing additives, the additive of the present disclosure has a greater alkali-reducing capability, and also significantly increases the efficiency, thus achieving environmental protection, cost reduction, and efficiency improvement.

Technical solutions: In order to achieve the objective of the present disclosure, technical solutions adopted in the present disclosure include:

A backside polishing additive for reducing alkali consumption includes components in percentages by mass as follows:
0.01% to 0.5% of a catalyst containing a nitrobenzene structure, 0.1% to 1% of a defoaming agent, 0.5% to 1.5% of a preservative, and a balance of water.

Preferably, the backside polishing additive includes components in percentages by mass as follows:
0.02% to 0.1% of the catalyst containing the nitrobenzene structure, 0.1% to 0.2% of the defoaming agent, 0.5% to 0.6% of the preservative, and the balance of water.

As a specific embodiment, the catalyst containing the nitrobenzene structure has a structural formula as follows:

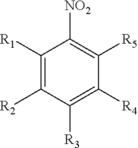

where, R₁, R₂, R₃, R₄, and R₅ are each independently selected from a group consisting of H, halogen, alkyl, alkoxy, amino, amido, aldehyde, hydrazinyl, sulfonic acid/sulfonate, phenol/phenolate, carboxyl, and ester groups.

Further, the R₁, the R₂, the R₃, the R₄, and the R₅ are each independently selected from a group consisting of H, halogen, C₁-C₁₀ alkyl, —NH₂, —(CH₂)ₘCONH₂, —(CH₂)ₚCHO, —NHNH₂, —SO₃R₆, —OR₇, and —COOR₈, where m and p are each a natural number, m is 0 to 5, and p is 0 to 5; the R₆ is selected from a group consisting of H and a metal atom; and the R₇ and the Ra are each independently selected from a group consisting of H, a metal atom, and C₁-C₈alkyl.

Preferably, the R₁, the R₂, the R₃, the R₄, and the R₅ are each independently selected from a group consisting of H, halogen, C₁-C₃ alkyl, —NH₂, —CONH₂, —CHO, —NHNH₂, —SO₃R₆, —OR₇, and —COOR₈; the R₆ is selected from a group consisting of H, Na, and K; the R₇ and the Ra are each independently selected from a group consisting of H, Na, K, and C₁-C₂ alkyl; and at least three of the R₁, the R₂, the R₃, the R₄, and the R₅ are H.

As a specific embodiment, the defoaming agent is one of, or a combination of two or more of polysaccharide-based compounds represented by a chemical formula (C₆H₁₀O₅)ₙ, where the C₆H₁₀O₅ represents a monosaccharide unit with one water molecule removed, and the n represents a number of the monosaccharide unit in the polysaccharide-based compounds.

As a specific embodiment, the defoaming agent is one of, or a combination of two or more of maltose, starch, lactose, cellulose, chitin, inulin, polymannose, and polyxylose.

As a specific embodiment, the preservative is an organic acid-based compound; and preferably, the preservative is one of, or a combination of two or more of succinic acid or a salt thereof, citric acid or a salt thereof, sorbic acid or a salt thereof, benzoic acid or a salt thereof, propionic acid or a salt thereof, acetic acid or a salt thereof, dehydroacetic acid or a salt thereof, lactic acid or a salt thereof, fumaric acid or a salt thereof, phenylalanine, propyl benzoate, paraben, and sulphite.

The present disclosure further provides a preparation method of the backside polishing additive for reducing the alkali consumption, including the following steps:
according to the percentages by mass, adding the catalyst containing the nitrobenzene structure, the defoaming agent, and the preservative to water, and uniformly mixing under stirring, to obtain the backside polishing additive.

The present disclosure further provides a method of using the backside polishing additive in backside polishing of a silicon wafer.

As a specific embodiment, the backside polishing additive is used in an alkali polishing reaction of the silicon wafer, to reduce alkali consumption.

As a specific embodiment, the use includes:
step (1) dissolving a pure alkali in water and uniformly mixing to obtain an alkali solution, and adding the backside polishing additive to the alkali solution and uniformly mixing to formulate a mixed polishing agent; and
step (2) immersing the silicon wafer in the mixed polishing agent for the alkali polishing reaction.

As a further embodiment:
In the step (1), the pure alkali is selected from a group consisting of NaOH and KOH; a mass concentration of the alkali solution is 0.2% to 0.7%; and a mass ratio of the backside polishing additive to the alkali solution is (0.3 to 1): 100; and
in the step (2), the alkali polishing reaction is conducted at a temperature controlled between 60° C. and 75° C. for 120 s to 240 s.

Beneficial effects: Compared with the prior art, the present disclosure has the following advantages:

(1) When applied to the alkali polishing reaction in silicon wafer production, the additive of the present disclosure modulates the anisotropic corrosive effect of alkali on the silicon wafer through the interaction between the surfactant and the surface of the silicon wafer. The rate of corrosion by OH-on the backside of the silicon wafer is promoted while ensuring that the PN junction on the front side of the silicon wafer is not destroyed. The present additive enables the polishing reaction at a required alkali concentration or consumption lower than a conventional additive. Therefore, the present additive has a greater alkali-reducing capability than the conventional additive, thereby reducing costs and environmental pollution in the production.

(2) The silicon wafer obtained through the use of the alkali polishing additive of the present disclosure for the alkali polishing reaction has a surface with a good flatness of the tower base and a high reflectivity, indicating a superior polishing effect, and resulting in a significant enhancement of the cell efficiency.

### BRIEF DESCRIPTION OF THE DRAWINGS

FIG. 1 shows a microscopic view of a polished surface of a silicon wafer obtained through the alkali polishing reaction in Example 2.

FIG. 2 shows a microscopic view of a polished surface of a silicon wafer obtained through the alkali polishing reaction in Comparative example 2.

### DETAILED DESCRIPTION OF THE EMBODIMENTS

The present disclosure is further described by the following examples. These examples are entirely illustrative, and are used only to specifically describe the present disclosure and should not be construed as a limitation of the present disclosure. The present disclosure is further described below in detail in combination with the appended drawings and examples.

### Example 1

Formulation of an additive: The additive was formulated by uniformly mixing 0.1 mass % of sodium m-nitrobenzenesulfonate as a catalyst, 0.2 mass % of maltose (n=2, C₁₂H₂₂O₁₁) as a defoaming agent, 0.5 mass % of succinic acid as a preservative, and the balance of deionized water.

450 L of deionized water was added into a 500-L alkali polishing reaction tank and heated to 70° C. Then 2 L of a 45 mass % NaOH solution was added into the alkali polishing reaction tank to obtain a mixture. The mixture was stirred until dissolved to obtain a 0.296% alkali solution. Then 1.5 L of the additive formulated above was added to the alkali solution to prepare a mixed polishing agent. Upon homogeneous circulation of a reaction liquid in the alkali polishing reaction tank, a silicon wafer was immersed in the alkali polishing reaction tank to undergo a polishing reaction for 200 s. After the alkali polishing reaction, the silicon wafer was advanced to a subsequent cell fabrication process, and a cell was finally made. Electrical performance indexes of the cell were tested.

### Comparative Example 1

450 L of deionized water was added into a 500-L alkali polishing reaction tank and heated to 70° C. Then 2 L of a 45 mass % NaOH solution was added into the alkali polishing reaction tank to obtain a mixture. The mixture was stirred until dissolved to obtain a 0.296% alkali solution. Then 1.5 L of a currently commercially available conventional alkali polishing additive (an alkali polishing additive with a perchlorate salt as the main catalytic ingredient) was added to the alkali solution. Upon homogeneous circulation of a reaction liquid in the alkali polishing reaction tank, a silicon wafer was immersed in the alkali polishing reaction tank to undergo a polishing reaction for 200 s. After the alkali polishing reaction, the silicon wafer was advanced to a subsequent cell fabrication process, and a cell was finally made. Electrical performance indexes of the cell were tested.

Table 1 shows the average electrical performance data of 1000 cells obtained through the alkali polishing reactions in Example 1 and Comparative example 1. According to the data in Table 1, it can be seen that under the condition of a low alkali dosage, the average efficiency of the cells made with the additive of the present disclosure is 26.78%, while the average efficiency of the cells made with the conventional additive is 26.43%. The use of the additive of the present disclosure shows an efficiency gain of 0.35% compared with the conventional additive. Therefore, the use of the additive of the present disclosure has a significant improvement effect on the conversion efficiency of the cells.

TABLE 1

| | Efficiency | Open-circuit | Short-circuit | Fill Factor |
|---|---|---|---|---|
| Additive | (η, %) | Voltage (Voc) | Current (Isc) | (FF) |
| Example 1 | 26.78 | 0.7373 | 14.149 | 85.47 |
| Comparative | 26.43 | 0.7361 | 14.152 | 85.36 |
| example 1 | | | | |

### Example 2

Formulation of an additive: The additive was formulated by uniformly mixing 0.1 mass % of sodium m-nitrobenzenesulfonate as a catalyst, 0.2 mass % of maltose (n=2, C₁₂H₂₂O₁₁) as a defoaming agent, 0.5 mass % of succinic acid as a preservative, and the balance of deionized water.

30 L of deionized water was added into a 40-L alkali polishing reaction tank and heated to 60° C. Then 100 g of NaOH was added into the alkali polishing reaction tank to obtain a mixture. The mixture was stirred until dissolved to obtain a 0.333% alkali solution. Then 100 g of the additive formulated above was added to the alkali solution and uniformly stirred to prepare a mixed polishing agent. A silicon wafer was immersed in the alkali polishing reaction tank to undergo a polishing reaction for 180 s. After the alkali polishing reaction, the silicon wafer was dried and subjected to a characterization analysis.

### Example 3

The additive and the mixed polishing agent were prepared according to the method of Example 2 to conduct the alkali polishing reaction, except that the additive was formulated by mixing 0.05 mass % of sodium p-nitrobenzoate as the catalyst, 0.1 mass % of lactose (n=2, C₁₂H₂₂O₁₁) as the defoaming agent, 0.6 mass % of benzoic acid as the preservative, and the balance of deionized water.

### Example 4

The additive and the mixed polishing agent were prepared according to the method of Example 2 to conduct the alkali polishing reaction, except that the catalyst in the additive was 0.07 mass % of p-nitrobenzenesulfonic acid.

### Example 5

The additive and the mixed polishing agent were prepared according to the method of Example 2 to conduct the alkali polishing reaction, except that the catalyst in the additive was 0.05 mass % of sodium 2-methoxy-5-nitrophenolate.

### Example 6

The additive and the mixed polishing agent were prepared according to the method of Example 2 to conduct the alkali polishing reaction, except that the catalyst in the additive was 0.04 mass % of potassium 2-methoxy-4-nitrophenolate.

### Example 7

The additive and the mixed polishing agent were prepared according to the method of Example 2 to conduct the alkali polishing reaction, except that the catalyst in the additive was 0.02 mass % of sodium 3-nitrobenzoate.

### Example 8

The additive and the mixed polishing agent were prepared according to the method of Example 2 to conduct the alkali polishing reaction, except that the catalyst in the additive was 0.08 mass % of p-nitrobenzoic acid.

### Example 9

The additive and the mixed polishing agent were prepared according to the method of Example 2 to conduct the alkali polishing reaction, except that the catalyst in the additive was 0.05 mass % of 2-nitroaniline.

### Example 10

The additive and the mixed polishing agent were prepared according to the method of Example 2 to conduct the alkali polishing reaction, except that the catalyst in the additive was 0.03 mass % of p-chloronitrobenzene.

### Example 11

The additive and the mixed polishing agent were prepared according to the method of Example 2 to conduct the alkali polishing reaction, except that the catalyst in the additive was 0.09 mass % of sodium 2-nitroaniline-4-sulfonate.

### Example 12

The additive and the mixed polishing agent were prepared according to the method of Example 2 to conduct the alkali polishing reaction, except that the catalyst in the additive was 0.06 mass % of methyl p-nitrobenzoate.

### Example 13

The additive and the mixed polishing agent were prepared according to the method of Example 2 to conduct the alkali polishing reaction, except that the catalyst in the additive was 0.03 mass % of 3-nitrobenzamide.

### Example 14

The additive and the mixed polishing agent were prepared according to the method of Example 2 to conduct the alkali polishing reaction, except that the catalyst in the additive was 0.04 mass % of p-nitrophenetole.

### Example 15

The additive and the mixed polishing agent were prepared according to the method of Example 2 to conduct the alkali polishing reaction, except that the catalyst in the additive was 0.07 mass % of p-nitrophenylhydrazine.

### Example 16

The additive and the mixed polishing agent were prepared according to the method of Example 2 to conduct the alkali polishing reaction, except that the catalyst in the additive was 0.02 mass % of 2-nitrobenzaldehyde.

### Comparative Example 2

The additive and the mixed polishing agent were prepared according to the method of Example 2 to conduct the alkali polishing reaction, except that the catalyst was a currently commercially available conventional alkali polishing additive (an alkali polishing additive with a perchlorate salt as the main catalytic ingredient).

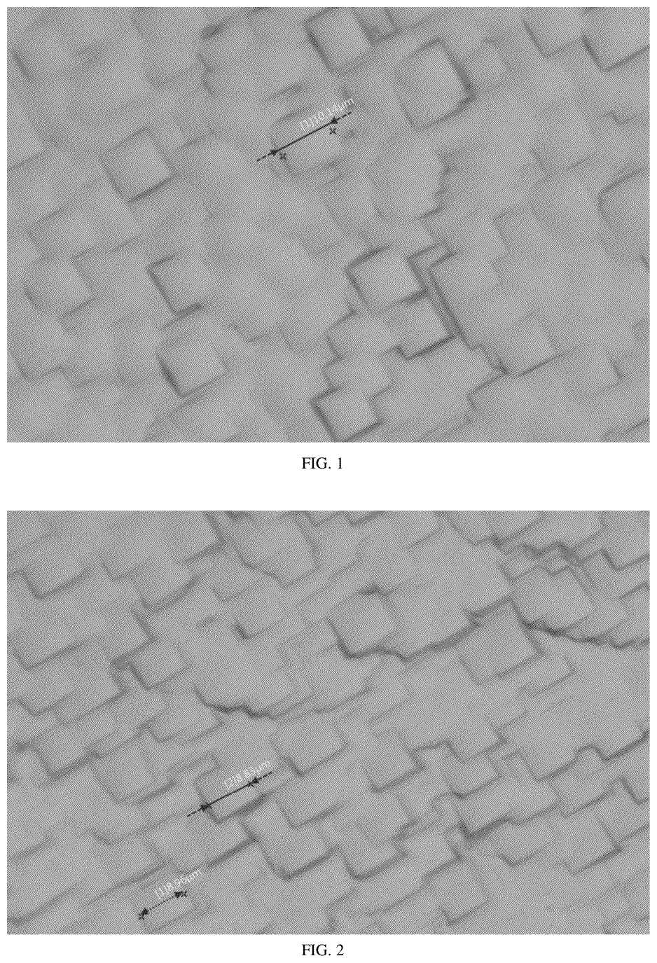

A microscopic view of the polished surface of the silicon wafer obtained by Example 2 is shown in FIG. 1, and a microscopic view of the polished surface of the silicon wafer obtained by Comparative example 2 is shown in FIG. 2. The characteristic data of the silicon wafers obtained through the reactions in Example 2 to Example 16 and Comparative example 2 is shown in Table 2. Combined with the data in Table 2, by comparing FIG. 1 with FIG. 2, it can be concluded that under a low alkali dosage, the silicon wafers made with the alkali polishing additive of the present disclosure (containing the catalyst of the nitrobenzene structure) had polished surfaces with a better flatness of the tower base, a larger size of the tower base, and a higher reflectivity compared with the commercially available conventional alkali polishing additive.

TABLE 2

| | Reduction | | |
|---|---|---|---|
| | in | | Tower Base Size |
| Additive | Mass (g) | Reflectivity (%) | (μm) |
| Example2 | 0.23 | 46.24 | 10-11 |
| Example 3 | 0.2 | 45.97 | 9-10 |
| Example 4 | 0.24 | 46.13 | 10-11 |
| Example 5 | 0.25 | 46.09 | 10-11 |
| Example 6 | 0.23 | 45.98 | 10-11 |
| Example 7 | 0.19 | 45.93 | 10-11 |
| Example 8 | 0.18 | 45.78 | 9-10 |
| Example 9 | 0.2 | 45.85 | 9-10 |
| Example 10 | 0.22 | 46.13 | 10-11 |
| Example 11 | 0.25 | 46.29 | 11-12 |
| Example 12 | 0.23 | 46.17 | 10-11 |
| Example 13 | 0.21 | 46.05 | 10-11 |
| Example 14 | 0.26 | 46.31 | 11-12 |
| Example 15 | 0.19 | 45.83 | 10-11 |
| Example 16 | 0.24 | 46.27 | 11-12 |
| Comparative | 0.15 | 43.67 | 8-9 |
| example2 | | | |

The foregoing description merely illustrates representative embodiments of the present disclosure and does not limit the protection scope of the present disclosure. It is to be emphasized that, any modifications and optimizations made by those skilled in the art without departing from the technical principles of the present disclosure shall be deemed to fall within the protection scope of the present disclosure.

1. A backside polishing additive for reducing alkali consumption, wherein the backside polishing additive comprises components in percentages by mass as follows:
0.01% to 0.5% of a catalyst containing a nitrobenzene structure, 0.1% to 1% of a defoaming agent, 0.5% to 1.5% of a preservative, and a balance of water.

2. The backside polishing additive for reducing the alkali consumption according to claim 1, wherein the catalyst containing the nitrobenzene structure has a structural formula as follows: 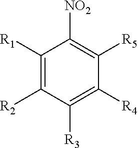
wherein, R₁, R₂, R₃, R₄, and R₅ are each independently selected from a group consisting of H, halogen, alkyl, alkoxy, amino, amido, aldehyde, hydrazinyl, sulfonic acid/sulfonate, phenol/phenolate, carboxyl, and ester groups.

3. The backside polishing additive for reducing the alkali consumption according to claim 2, wherein the R₁, the R₂, the R₃, the R₄, and the R₅ are each independently selected from a group consisting of H, halogen, C₁-C₁₀ alkyl, —NH₂, —(CH₂)ₘCONH₂, —(CH₂)ₚCHO, —NHNH₂, —SO₃R₆, —OR₇, and —COOR₈, wherein the m and the p are each a natural number, the m is 0 to 5, and the p is 0 to 5; the R₆ is selected from a group consisting of H and a metal atom; and the R₇ and the R₈ are each independently selected from a group consisting of H, a metal atom, and C₁-C₈alkyl.

4. The backside polishing additive for reducing the alkali consumption according to claim 2, wherein the R₁, the R₂, the R₃, the R₄, and the R₅ are each independently selected from a group consisting of H, halogen, C₁-C₃ alkyl, —NH₂, —CONH₂, —CHO, —NHNH₂, —SO₃R₆, —OR₇, and —COOR₈; the R₆ is selected from a group consisting of H, Na, and K; the R₇ and the R₈ are each independently selected from a group consisting of H, Na, K, and C₁-C₂ alkyl; and at least three of the R₁, the R₂, the R₃, the R₄, and the R₅ are H.

5. The backside polishing additive for reducing the alkali consumption according to claim 1, wherein the defoaming agent is one of, or a combination of two or more of polysaccharide-based compounds represented by a chemical formula (C₆H₁₀O₅)ₙ, wherein the C₆H₁₀O₅ represents a monosaccharide unit with one water molecule removed, the n represents a number of the monosaccharide unit in the polysaccharide-based compounds, and the preservative is an organic acid-based compound.

6. The backside polishing additive for reducing the alkali consumption according to claim 5, wherein the defoaming agent is one of, or a combination of two or more of maltose, starch, lactose, cellulose, chitin, inulin, polymannose, and polyxylose.

7. The backside polishing additive for reducing the alkali consumption according to claim 5, wherein the preservative is one of, or a combination of two or more of succinic acid or a salt of the succinic acid, citric acid or a salt of the citric acid, sorbic acid or a salt of the sorbic acid, benzoic acid or a salt of the benzoic acid, propionic acid or a salt of the propionic acid, acetic acid or a salt of the acetic acid, dehydroacetic acid or a salt of the dehydroacetic acid, lactic acid or a salt of the lactic acid, fumaric acid or a salt of the fumaric acid, phenylalanine, propyl benzoate, paraben, and sulphite.

8. A preparation method of the backside polishing additive for reducing the alkali consumption according to claim 1, wherein the preparation method comprises the following steps:
according to the percentages by mass, adding the catalyst containing the nitrobenzene structure, the defoaming agent, and the preservative to the water, and uniformly mixing under stirring, to obtain the backside polishing additive.

9. A method of using the backside polishing additive according to claim 1 in backside polishing of a silicon wafer, wherein the backside polishing additive is used in an alkali polishing reaction of the silicon wafer to reduce alkali consumption, and the method comprises:
step (1) dissolving a pure alkali in water and uniformly mixing to obtain an alkali solution, and adding the backside polishing additive to the alkali solution and uniformly mixing to formulate a mixed polishing agent; and
step (2) immersing the silicon wafer in the mixed polishing agent for the alkali polishing reaction.

10. The method according to claim 9, wherein:
in the step (1), the pure alkali is selected from a group consisting of NaOH and KOH; a mass concentration of the alkali solution is 0.2% to 0.7%; and a mass ratio of the backside polishing additive to the alkali solution is (0.3 to 1): 100; and
in the step (2), the alkali polishing reaction is conducted at a temperature controlled between 60° C. and 75° C. for 120 s to 240 s.

11. A preparation method of the backside polishing additive for reducing the alkali consumption according to claim 2, wherein the preparation method comprises the following steps:
according to the percentages by mass, adding the catalyst containing the nitrobenzene structure, the defoaming agent, and the preservative to the water, and uniformly mixing under stirring, to obtain the backside polishing additive.

12. A preparation method of the backside polishing additive for reducing the alkali consumption according to claim 3, wherein the preparation method comprises the following steps:
according to the percentages by mass, adding the catalyst containing the nitrobenzene structure, the defoaming agent, and the preservative to the water, and uniformly mixing under stirring, to obtain the backside polishing additive.

13. A preparation method of the backside polishing additive for reducing the alkali consumption according to claim 4, wherein the preparation method comprises the following steps:
according to the percentages by mass, adding the catalyst containing the nitrobenzene structure, the defoaming agent, and the preservative to the water, and uniformly mixing under stirring, to obtain the backside polishing additive.

14. A preparation method of the backside polishing additive for reducing the alkali consumption according to claim 5, wherein the preparation method comprises the following steps:
according to the percentages by mass, adding the catalyst containing the nitrobenzene structure, the defoaming agent, and the preservative to the water, and uniformly mixing under stirring, to obtain the backside polishing additive.

15. A method of using the backside polishing additive according to claim 2 in backside polishing of a silicon wafer wherein the backside polishing additive is used in an alkali polishing reaction of the silicon wafer to reduce alkali consumption, and the method comprises:
step (1) dissolving a pure alkali in water and uniformly mixing to obtain an alkali solution, and adding the backside polishing additive to the alkali solution and uniformly mixing to formulate a mixed polishing agent; and
step (2) immersing the silicon wafer in the mixed polishing agent for the alkali polishing reaction.

16. A method of using the backside polishing additive according to claim 3 in backside polishing of a silicon wafer, wherein the backside polishing additive is used in an alkali polishing reaction of the silicon wafer to reduce alkali consumption, and the method comprises:
step (1) dissolving a pure alkali in water and uniformly mixing to obtain an alkali solution, and adding the backside polishing additive to the alkali solution and uniformly mixing to formulate a mixed polishing agent; and
step (2) immersing the silicon wafer in the mixed polishing agent for the alkali polishing reaction.

17. A method of using the backside polishing additive according to claim 4 in backside polishing of a silicon wafer, wherein the backside polishing additive is used in an alkali polishing reaction of the silicon wafer to reduce alkali consumption, and the method comprises:
step (1) dissolving a pure alkali in water and uniformly mixing to obtain an alkali solution, and adding the backside polishing additive to the alkali solution and uniformly mixing to formulate a mixed polishing agent; and
step (2) immersing the silicon wafer in the mixed polishing agent for the alkali polishing reaction.

18. A method of using the backside polishing additive according to claim 5 in backside polishing of a silicon wafer, wherein the backside polishing additive is used in an alkali polishing reaction of the silicon wafer to reduce alkali consumption, and the method comprises:
step (1) dissolving a pure alkali in water and uniformly mixing to obtain an alkali solution, and adding the backside polishing additive to the alkali solution and uniformly mixing to formulate a mixed polishing agent; and
step (2) immersing the silicon wafer in the mixed polishing agent for the alkali polishing reaction.

19. A method of using the backside polishing additive according to claim 6 in backside polishing of a silicon wafer, wherein the backside polishing additive is used in an alkali polishing reaction of the silicon wafer to reduce alkali consumption, and the method comprises:
step (1) dissolving a pure alkali in water and uniformly mixing to obtain an alkali solution, and adding the backside polishing additive to the alkali solution and uniformly mixing to formulate a mixed polishing agent; and
step (2) immersing the silicon wafer in the mixed polishing agent for the alkali polishing reaction.

20. A method of using the backside polishing additive according to claim 7 in backside polishing of a silicon wafer, wherein the backside polishing additive is used in an alkali polishing reaction of the silicon wafer to reduce alkali consumption, and the method comprises:
step (1) dissolving a pure alkali in water and uniformly mixing to obtain an alkali solution, and adding the backside polishing additive to the alkali solution and uniformly mixing to formulate a mixed polishing agent; and
step (2) immersing the silicon wafer in the mixed polishing agent for the alkali polishing reaction.
